(19) United States
(12) Patent Application Publication
(10) Pub. No.: US 2025/0098242 A1
(43) Pub. Date: Mar. 20, 2025

(54) AIR GAP INSULATION IN PLACE OF GATE SPACERS

(71) Applicant: Intel Corporation, Santa Clara, CA (US)

(72) Inventors: Seda Cekli, Portland, OR (US); Makram Abd El Qader, Hillsboro, OR (US); Sudipto Naskar, Portland, OR (US); Anh Phan, Beaverton, OR (US); Rishabh Mehandru, Portland, OR (US)

(73) Assignee: Intel Corporation, Santa Clara, CA (US)

(21) Appl. No.: 18/467,906

(22) Filed: Sep. 15, 2023

(51) Int. Cl. H01L 29/06; H01L 21/8238; H01L 27/092; H01L 29/78

(52) U.S. Cl. CPC H10D 62/123; H10D 30/63; H10D 62/116; H10D 62/121; H10D 84/017; H10D 84/038; H10D 84/856

(57) ABSTRACT

IC structures with air gap insulation in place of gate spacers are disclosed. An example IC structure includes a transistor comprising a channel region and a source or drain (S/D) region, a gate structure coupled to the channel region and comprising a gate electrode material and a first electrically conductive material, a S/D contact structure coupled to the S/D region and comprising a second electrically conductive material, a gap between the gate structure and the S/D contact structure, and a liner material on at least a portion of a sidewall of the gap, the liner material comprising aluminum and oxygen.

### BACKGROUND

For the past several decades, the scaling of features in integrated circuits (ICs) has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize fabrication and performance of each component (e.g., of each transistor) is becoming increasingly significant.

### BRIEF DESCRIPTION OF THE DRAWINGS

Embodiments will be readily understood by the following detailed description in conjunction with the accompanying drawings.

FIG. 1 provides a perspective view of an example nanoribbon field-effect transistor (FET), according to some embodiments of the present disclosure.

FIGS. 2A-2B is a flow diagram of an example method for fabricating an IC structure with air gap insulation in place of gate spacers, in accordance with some embodiments.

FIGS. 3A-3R provide cross-sectional side views at various stages in the fabrication of an example IC structure according to the method of FIGS. 2A-2B, in accordance with some embodiments.

FIGS. 4A-4D provide cross-sectional side views illustrating characteristic features that may be present in IC structures as a result of performing the method of FIGS. 2A-2B, in accordance with some embodiments.

FIG. 5 is a top view of a wafer and dies that may include any of the IC structures disclosed herein, in accordance with any of the embodiments disclosed herein.

FIG. 6 is a side, cross-sectional view of an IC device that may include any of the IC structures disclosed herein, in accordance with any of the embodiments disclosed herein.

FIG. 7 is a side, cross-sectional view of an IC package that may include any of the IC structures disclosed herein, in accordance with various embodiments.

FIG. 8 is a side, cross-sectional view of an IC device assembly that may include any of the IC structures disclosed herein, in accordance with any of the embodiments disclosed herein.

FIG. 9 is a block diagram of an example electrical device that may include any of the IC structures disclosed herein, in accordance with any of the embodiments disclosed herein.

### DETAILED DESCRIPTION

Disclosed herein is a fabrication method and associated IC structures, and devices. The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

As briefly described above, scaling down features in ICs has fueled the semiconductor industry's growth. Smaller features mean more functions on chips, boosting capacity. Optimizing fabrication and performance of each individual component is crucial in the pursuit of greater capacity. One factor limiting performance is capacitance. It can slow down the operation of transistors and other components, impacting speed and power consumption. High capacitance can also lead to crosstalk, which is unwanted interference between adjacent components.

Capacitance is a concern whenever two metal structures are placed in close proximity to each other in an IC. A prominent example is having a source contact and a drain contact on either side of a gate contact of a FET, since such contacts are metal structures. Conventional transistors employ gate spacers of solid dielectric materials to help isolate the gate contact from the source/drain (S/D) contacts. Gate spacers create a physical gap between the gate and the S/D contacts and help prevent unintended electrical interactions between these components, ensuring that the transistor functions as intended.

Since capacitance is directly proportional to the dielectric constant of the material between the plates of a capacitor, reducing the dielectric constant of gate spacers could result in reduced capacitance associated with the proximity of gate and S/D contacts. Air, being a gas, has a very low k-value that approximates the theoretical limit of 1.0. Therefore, when air is used as an insulator or to create gaps between conductive elements in ICs, it significantly reduces the capacitance compared to solid dielectric isolation.

Providing air gap insulation in place of gate spacers of transistors may provide one venue for optimizing performance of transistors and IC structures in which they are implemented. Being able to at least partially etch away the gate spacers once gate and S/D contacts have been formed, leaving air in their place, could provide tremendous benefits in terms of reduced capacitance. However, gate spacer etch possesses very high risk and challenges due to selectivity requirements and varying critical material exposure that can impact yield negatively.

Various embodiments of a fabrication method proposed herein may help improve on one or more challenges described above, e.g., may help reduce the risk and challenges associated with the etch of gate spacers, making air gap insulation in place of gate spacers feasible. IC structures with air gap insulation in place of gate spacers fabricated using the method described herein may possess several features characteristic of the use of the method. For example, in one aspect, an example IC structure includes a transistor comprising a channel region and a S/D region, a gate structure coupled to the channel region and comprising a gate electrode material and a first electrically conductive material, a S/D contact structure coupled to the S/D region and comprising a second electrically conductive material, a gap between the gate structure and the S/D contact structure, and a liner material on at least a portion of a sidewall of the gap, the liner material comprising aluminum and oxygen. The gap may provide air gap insulation and may be in place of a gate spacer. As used herein, “air gap insulation in place of gate spacers” covers scenarios where gaps filled with air fully replace one or more gate spacers, scenarios where gaps filled with air partially replace one or more gate spacers, and where any of such gaps are filled with a gas other than air.

IC structures as described herein, in particular IC structures with air gap insulation in place of gate spacers, may be implemented in one or more components associated with an IC or/and between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. In some embodiments, IC structures as described herein may be included in a radio frequency IC (RFIC), which may, e.g., be included in any component associated with an IC of an RF receiver, an RF transmitter, or an RF transceiver, e.g., as used in telecommunications within base stations (BS) or user equipment (UE). Such components may include, but are not limited to, power amplifiers, low-noise amplifiers, RF filters (including arrays of RF filters, or RF filter banks), switches, upconverters, downconverters, and duplexers. In some embodiments, IC structures as described herein may be included in memory devices or circuits. In some embodiments, IC structures as described herein may be employed as part of a chipset for executing one or more related functions in a computer.

For purposes of explanation, specific numbers, materials and configurations are set forth in order to provide a thorough understanding of the illustrative implementations. However, it will be apparent to one skilled in the art that the present disclosure may be practiced without the specific details or/and that the present disclosure may be practiced with only some of the described aspects.

In other instances, well-known features are omitted or simplified in order not to obscure the illustrative implementations. The terms “substantially,” “close,” “approximately,” “near,” and “about,” generally refer to being within +/−10% of a target value, e.g., within +/−5% of a target value, based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−10% of a target value, e.g., within +/−5% of a target value, based on the context of a particular value as described herein or as known in the art.

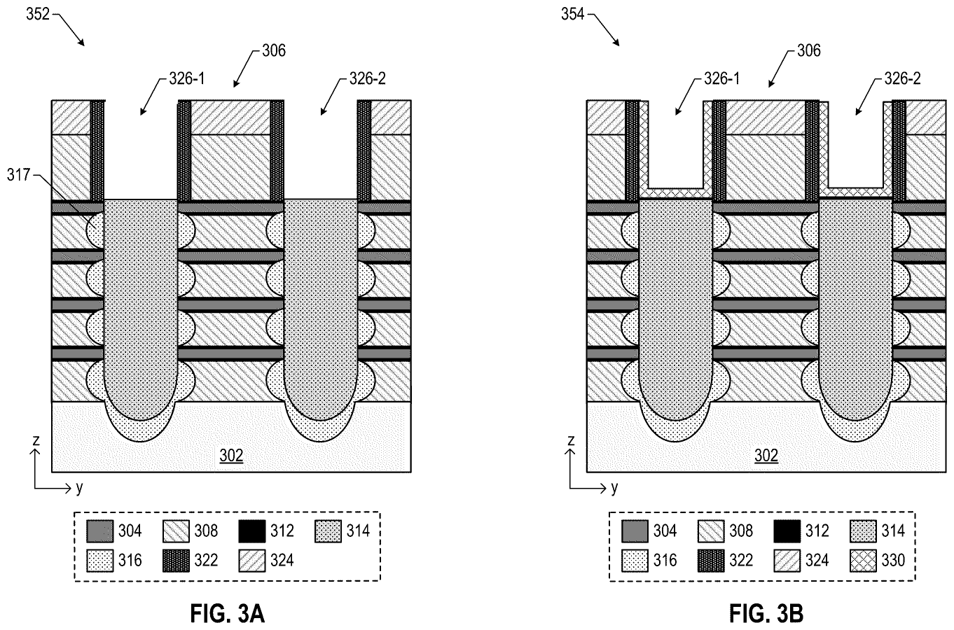

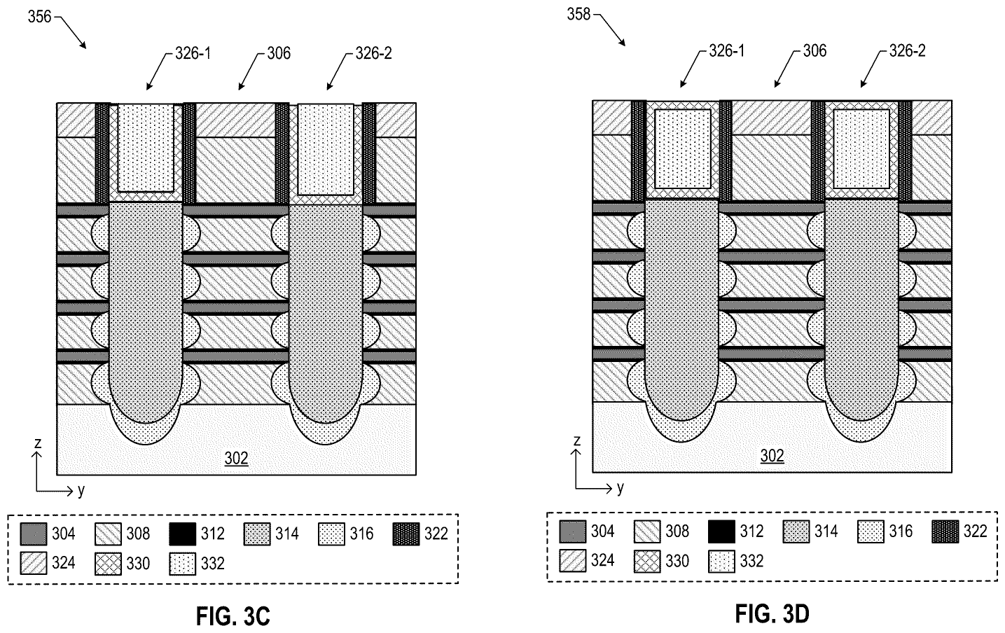

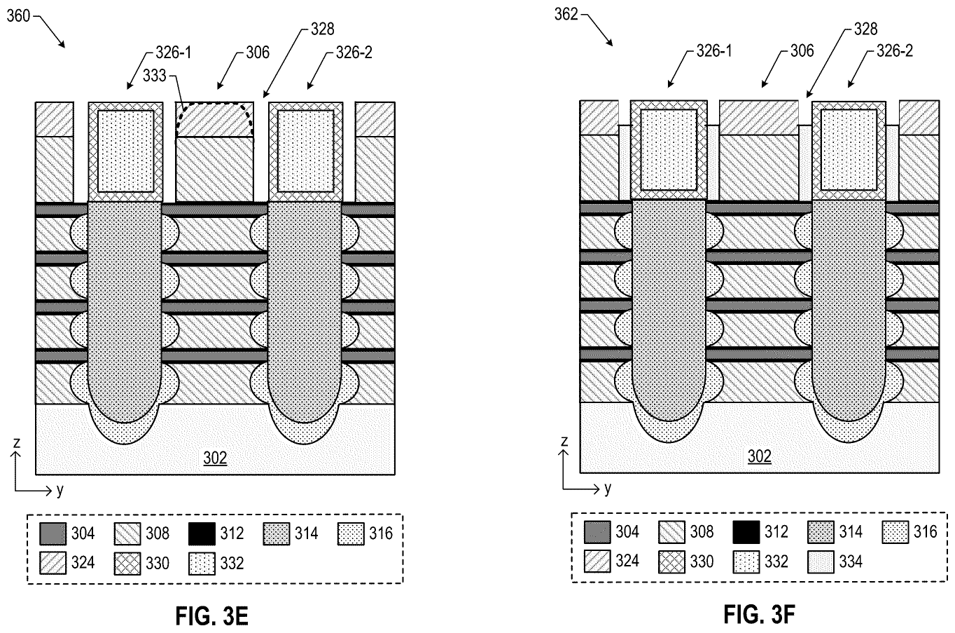

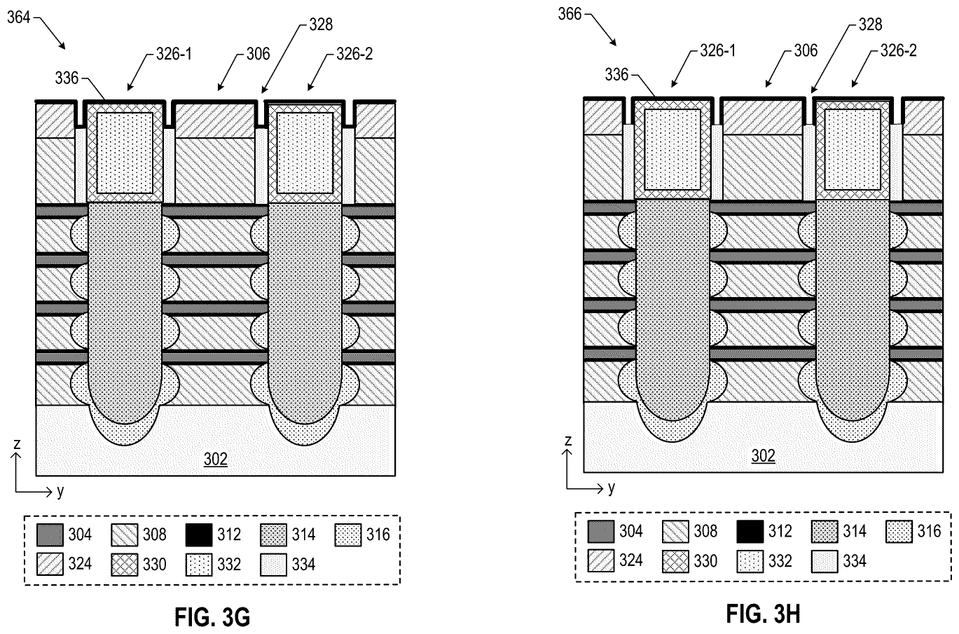

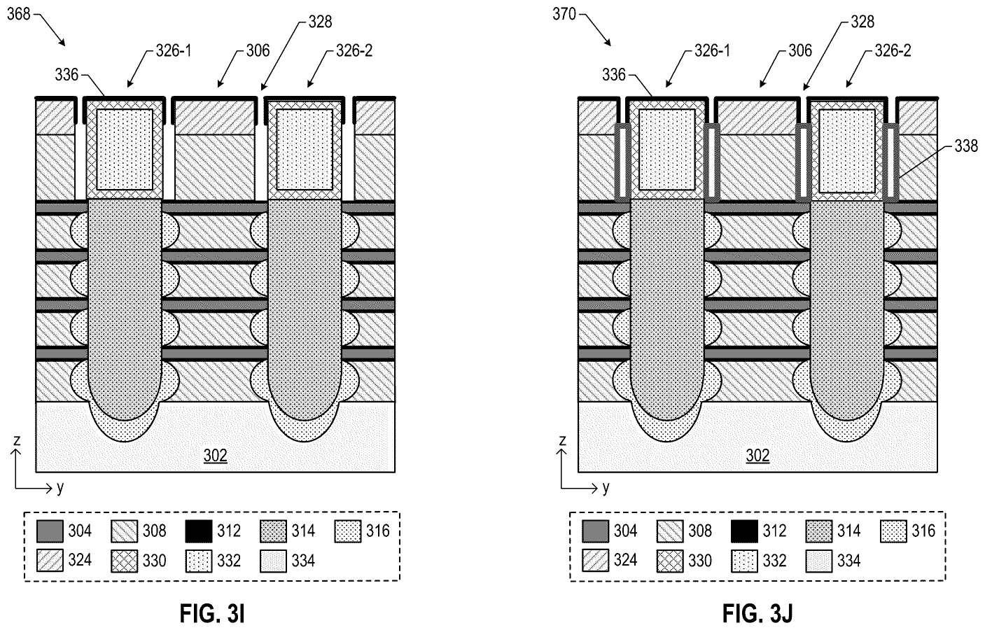

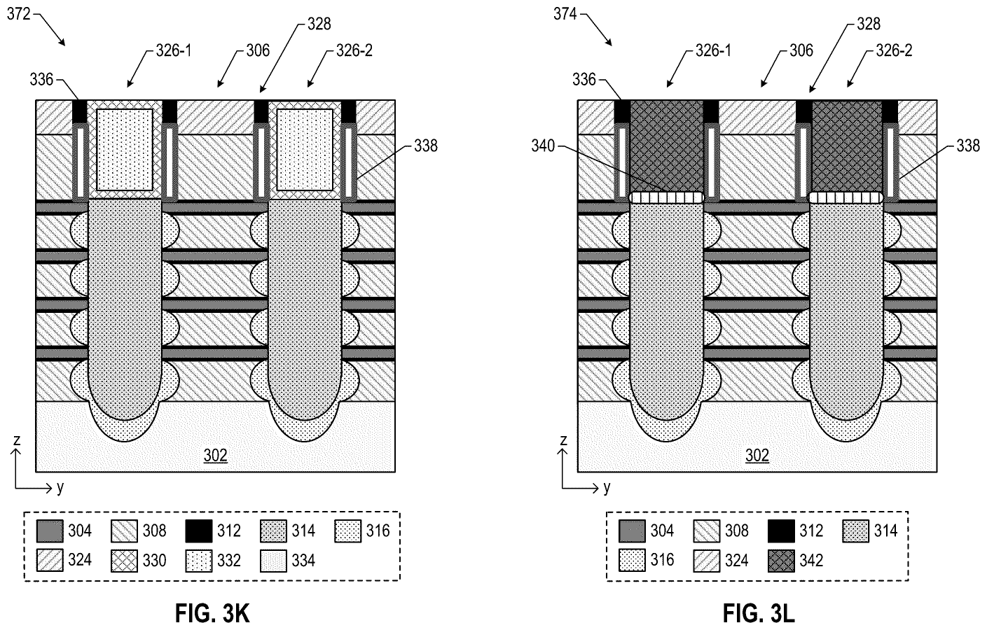

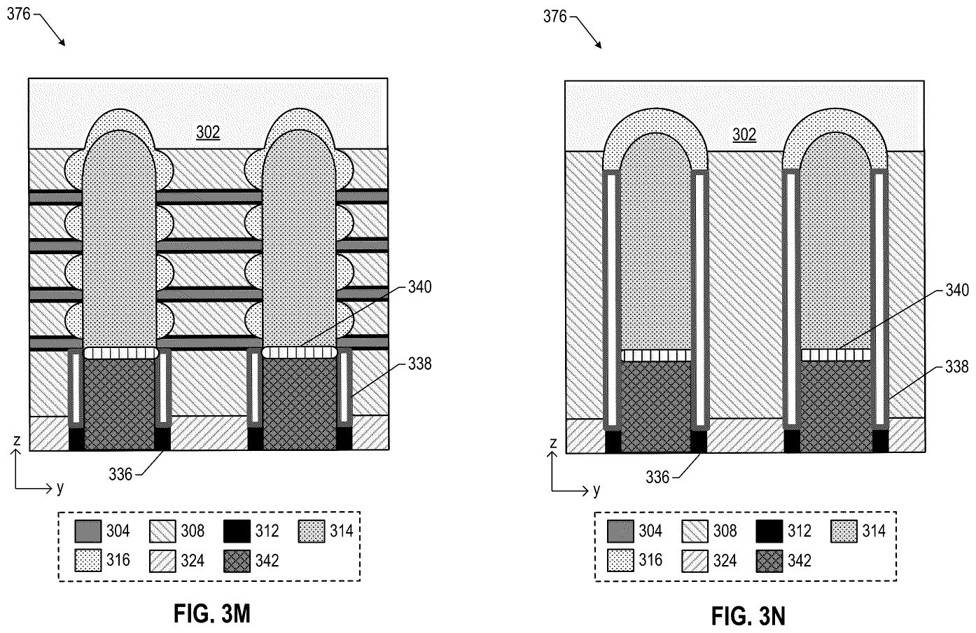

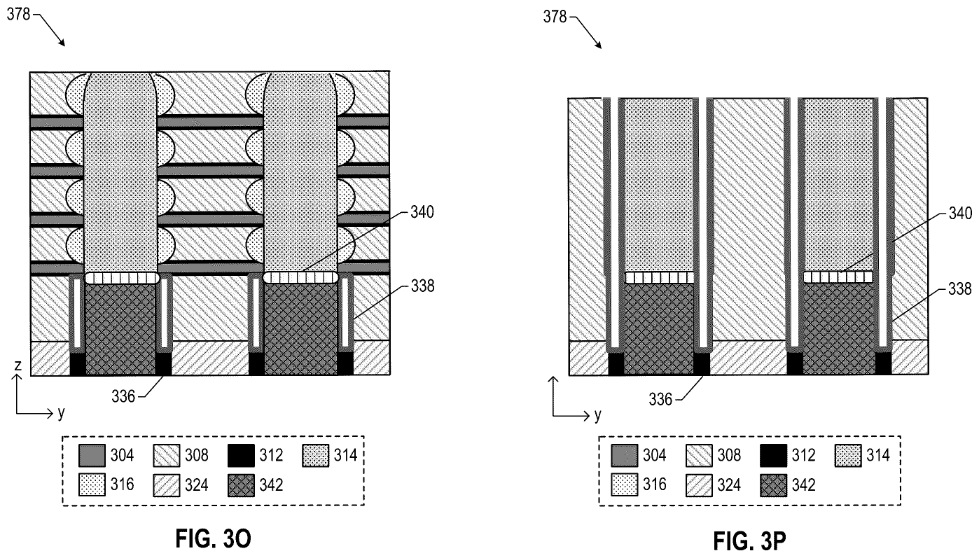

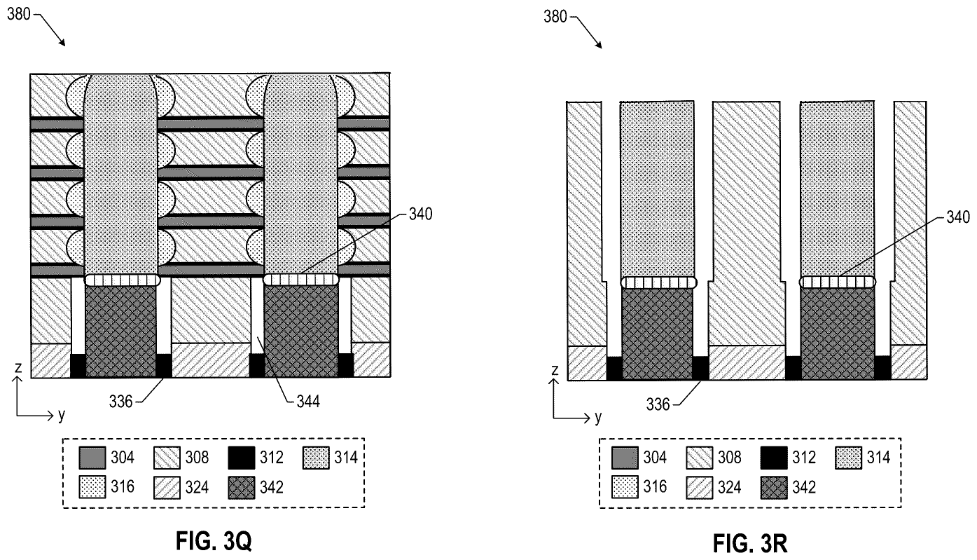

In the following description, references are made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense. For convenience, if a collection of drawings designated with different letters are present, e.g., FIGS. 3A-3R, such a collection may be referred to herein without the letters, e.g., as “FIG. 3.”

In the drawings, while some schematic illustrations of example structures of various devices and assemblies described herein may be shown with precise right angles and straight lines, this is simply for ease of illustration, and embodiments of these assemblies may be curved, rounded, or otherwise irregularly shaped as dictated by, and sometimes inevitable due to, the fabricating processes used to fabricate semiconductor device assemblies. Therefore, it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of IC structures with air gap insulation in place of gate spacers as described herein.

Various aspects of the illustrative implementations will be described using terms commonly employed by those skilled in the art to convey the substance of their work to others skilled in the art. For example, the terms “oxide,” “carbide,” “nitride,” “silicide,” etc. refer to compounds containing, respectively, oxygen, carbon, nitrogen, silicon, etc.; the term “high-k dielectric” refers to a material having a higher dielectric constant than silicon oxide; the term “low-k dielectric” refers to a material having a lower dielectric constant than silicon oxide. Materials referred to herein with formulas or as compounds cover all materials that include elements of the formula or a compound, e.g., TiSi or titanium silicide may refer to any material that includes titanium and silicon, WN or tungsten nitride may refer to any material that includes tungsten and nitrogen, etc. The term “insulating” means “electrically insulating,” the term “conducting” means “electrically conducting,” unless otherwise specified. Furthermore, the term “connected” may be used to describe a direct electrical or magnetic connection between the things that are connected, without any intermediary devices, while the term “coupled” may be used to describe either a direct electrical or magnetic connection between the things that are connected, or an indirect connection through one or more passive or active intermediary devices. A first component described to be electrically coupled to a second component means that the first component is in conductive contact with the second component (i.e., that a conductive pathway is provided to route electrical signals/power between the first and second components).

Various operations may be described as multiple discrete actions or operations in turn, in a manner that is most helpful in understanding the claimed subject matter. However, the order of description should not be construed as to imply that these operations are necessarily order dependent. These operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges.

The description uses the phrases “in an embodiment” or “in embodiments,” which may each refer to one or more of the same or different embodiments. The terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner. Although some materials may be described in singular form, such materials may include a plurality of materials, e.g., a semiconductor material may include two or more different semiconductor materials.

A fabrication method for forming IC structures with air gap insulation in place of gape spacers, presented herein, may be carried out with transistors of any architecture, such as any non-planar or planar architecture. Non-planar transistors such as double-gate transistors, tri-gate transistors, FinFETs, and nanowire/nanoribbon/nanosheet transistors refer to transistors having a non-planar architecture. In comparison to a planar architecture where the transistor channel has only one confinement surface, a non-planar architecture is any type of architecture where the transistor channel has more than one confinement surfaces. A confinement surface refers to a particular orientation of the channel surface that is confined by the gate field. Non-planar transistors potentially improve performance relative to transistors having a planar architecture, such as single-gate transistors.

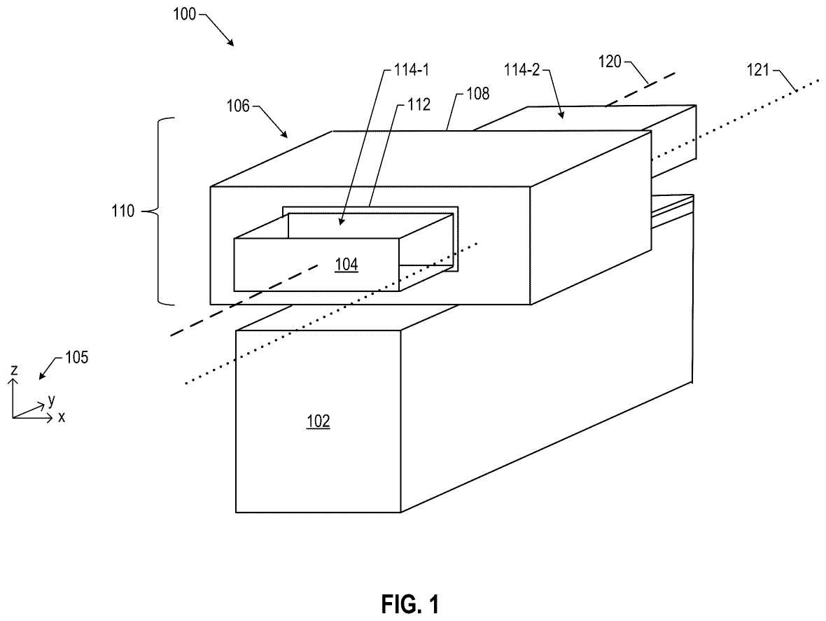

Nanoribbon transistors may be particularly advantageous for continued scaling of complementary metal-oxide-semiconductor (CMOS) technology nodes due to the potential to form gates on all four sides of a channel material (hence, such transistors are sometimes referred to as “gate all around” transistors). Therefore, some IC structures illustrated herein show nanoribbon transistors as an example (e.g., IC structures shown in FIG. 1 and FIGS. 3A-3R), although the fabrication method described herein is not limited to such transistors.

As used herein, the term “nanoribbon” refers to an elongated structure of a semiconductor material having a longitudinal axis parallel to a support structure (e.g., a substrate, a die, a chip, or a wafer) over which such a structure is built. Typically, a length of a such a structure (i.e., a dimension measured along the longitudinal axis, shown in the present drawings to be along the y-axis of an example x-y-z coordinate system 105 shown in FIG. 1) is greater than each of a width (i.e., a dimension measured along the x-axis of the coordinate system 105) and a thickness/height (i.e., a dimension measured along the z-axis of the coordinate system 105). In some settings, the terms “nanoribbon” or “nanosheet” have been used to describe elongated semiconductor structures that have a rectangular transverse cross-section (i.e., a cross-section in a plane perpendicular to the longitudinal axis of the structure), while the term “nanowire” has been used to describe similar elongated structures but with circular transverse cross-sections. In the present disclosure, the term “nanoribbon” is used to refer to all such nanowires, nanoribbons, and nanosheets, as well as elongated semiconductor structures with a longitudinal axis parallel to the support structures and with having transverse cross-sections of any geometry (e.g., transverse cross-sections in the shape of an oval or a polygon with rounded corners). A transistor may then be described as a “nanoribbon transistor” if the channel of the transistor is a portion of a nanoribbon, i.e., a portion around which a gate stack of a transistor may wrap around. The semiconductor material in the portion of the nanoribbon that forms a channel of a transistor may be referred to as a “channel material,” with source and drain regions of a transistor provided on either side of the channel material.

FIG. 1 provides a perspective view of an example IC structure 100 with a nanoribbon transistor 110, according to some embodiments of the present disclosure. As shown in FIG. 1, the IC structure 100 includes a semiconductor material formed as a nanoribbon 104 extending substantially parallel to a support 102. The transistor 110 may be formed on the basis of the nanoribbon 104 by having a gate stack 106 wrap around at least a portion of the nanoribbon referred to as a “channel portion” and by having source and drain regions, shown in FIG. 1 as a first S/D region 114-1 and a second S/D region 114-2, on either side of the gate stack 106. One of the S/D regions 114 is a source region and the other one is a drain region. However, because, as is common in the field of FETs, designations of source and drain are often interchangeable, they are simply referred to herein as a first S/D region 114-1 and a second S/D region 114-2.

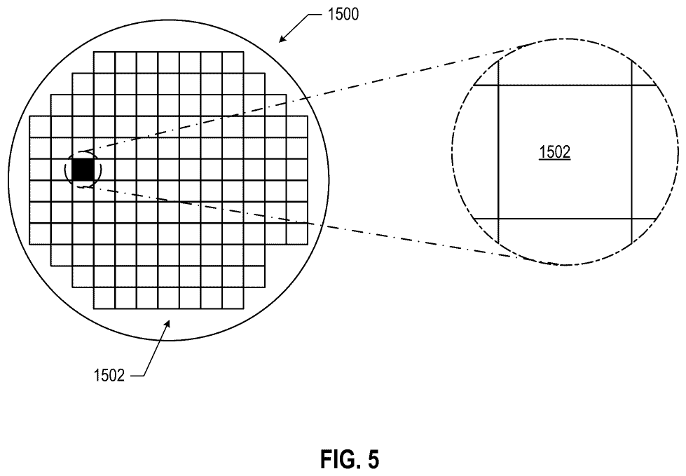

Implementations of the present disclosure may be formed or carried out on any suitable support 102, such as a substrate, a die, a wafer, or a chip. The support 102 may, e.g., be the wafer 1500 of FIG. 5, discussed below, and may be, or be included in, a die, e.g., the singulated die 1502 of FIG. 5, discussed below. The support 102 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group Ill-V materials (i.e., materials from groups Ill and V of the periodic system of elements), group II-VI (i.e., materials from groups II and IV of the periodic system of elements), or group IV materials (i.e., materials from group IV of the periodic system of elements). In some embodiments, the substrate may be non-crystalline. In some embodiments, the support 102 may be a printed circuit board (PCB) substrate, a package substrate, an interposer, a wafer, or a die.

Although a few examples of materials from which the support 102 may be formed are described here, any material that may serve as a foundation upon which an IC structure with air gap insulation in place of gate spacers as described herein may be built falls within the spirit and scope of the present disclosure. Although only one nanoribbon 104 is shown in FIG. 1, the IC structure 100 may include a stack of such nanoribbons where a plurality of nanoribbons 104 are stacked above one another, e.g., as is shown in FIGS. 3A-3R showing IC structures that may be examples of the IC structure 100. In some embodiments, a portion of the support 102 right below the lowest nanoribbon 104 of the stack may be shaped as a subfin extending away from a base, as is known in the field of nanoribbon transistors.

The nanoribbon 104 may take the form of a nanowire or nanoribbon, for example. In some embodiments, an area of a transversal cross-section of the nanoribbon 104 (i.e., an area in the x-z plane of the coordinate system 105 shown in FIG. 1, perpendicular to a longitudinal axis 120 of the nanoribbon 104) may be between about 25 and 10000 square nanometers, including all values and ranges therein (e.g., between about 25 and 1000 square nanometers, or between about 25 and 500 square nanometers). In some embodiments, a width of the nanoribbon 104 (i.e., a dimension measured in a plane parallel to the support 102 and in a direction perpendicular to the longitudinal axis 120 of the nanoribbon 104, e.g., along the x-axis of the coordinate system 105) may be at least about 3 times larger than a height of the nanoribbon 104 (i.e., a dimension measured in a plane perpendicular to the support 102, e.g., along the z-axis of the coordinate system 105), including all values and ranges therein, e.g., at least about 4 times larger, or at least about 5 times larger. Although the nanoribbon 104 illustrated in FIG. 1 is shown as having a rectangular cross-section, the nanoribbon 104 may instead have a cross-section that is rounded at corners or otherwise irregularly shaped, and the gate stack 106 may conform to the shape of the nanoribbon 104. The term “face” of a nanoribbon may refer to the side of the nanoribbon 104 that is larger than the side perpendicular to it (when measured in a plane substantially perpendicular to the longitudinal axis 120 of the nanoribbon 104), the latter side being referred to as a “sidewall” of a nanoribbon.

In various embodiments, the semiconductor material of the nanoribbon 104 may be composed of semiconductor material systems including, for example, N-type or P-type materials systems. In some embodiments, the nanoribbon 104 may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the nanoribbon 104 may include a combination of semiconductor materials. In some embodiments, the nanoribbon 104 may include a monocrystalline semiconductor, such as silicon (Si) or germanium (Ge). In some embodiments, the nanoribbon 104 may include a compound semiconductor with a first sub-lattice of at least one element from group III of the periodic table (e.g., Al, Ga, In), and a second sub-lattice of at least one element of group V of the periodic table (e.g., P, As, Sb).

For some example N-type transistor embodiments (i.e., for the embodiments where the transistor 110 is an N-type metal-oxide-semiconductor (NMOS) transistor), the channel material of the nanoribbon 104 may include a Ill-V material having a relatively high electron mobility, such as, but not limited to InGaAs, InP, InSb, and InAs. For some such embodiments, the channel material of the nanoribbon 104 may be a ternary Ill-V alloy, such as InGaAs, GaAsSb, InAsP, or InPSb. For some InₓGa₁₋ₓAs fin embodiments, In content (x) may be between 0.6 and 0.9, and may advantageously be at least 0.7 (e.g., In_{0.7}Ga_{0.3}As). For some example P-type transistor embodiments (i.e., for the embodiments where the transistor 110 is a P-type metal-oxide-semiconductor (PMOS) transistor), the channel material of the nanoribbon 104 may advantageously be a group IV material having a high hole mobility, such as, but not limited to Ge or a Ge-rich SiGe alloy. For some example embodiments, the channel material of the nanoribbon 104 may have a Ge content between 0.6 and 0.9, and advantageously may be at least 0.7.

In some embodiments, the channel material of the nanoribbon 104 may be a thin-film material, such as a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, if the transistor formed in the nanoribbon is a thin-film transistor (TFT), the channel material of the nanoribbon 104 may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphite, and black phosphorus, each of which may possibly be doped with one or more of gallium, indium, aluminum, fluorine, boron, phosphorus, arsenic, nitrogen, tantalum, tungsten, and magnesium, etc. In some embodiments, the channel material of the nanoribbon 104 may have a thickness between about 5 and 75 nanometers, including all values and ranges therein. In some embodiments, a thin-film channel material may be deposited at relatively low temperatures, which allows depositing the channel material within the thermal budgets imposed on back-end fabrication to avoid damaging other components, e.g., front-end components such as the logic devices.

A gate stack 106 including a gate electrode material 108 and, optionally, a gate insulator material 112, may wrap entirely or almost entirely around a portion of the nanoribbon 104 as shown in FIG. 1, with the active region (channel region) of the channel material of the transistor 110 corresponding to the portion of the nanoribbon 104 wrapped by the gate stack 106. As shown in FIG. 1, the gate insulator material 112 may wrap around a transversal portion of the nanoribbon 104 and the gate electrode material 108 may wrap around the gate insulator material 112.

The gate electrode material 108 may include one or more gate electrode materials, where the choice of the gate electrode materials may depend on whether the transistor 110 is a PMOS transistor or an NMOS transistor. For a PMOS transistor, gate electrode materials that may be used in different portions of the gate electrode material 108 may include, but are not limited to, ruthenium, palladium, platinum, cobalt, nickel, and conductive metal oxides (e.g., ruthenium oxide). For an NMOS transistor, gate electrode materials that may be used in different portions of the gate electrode material 108 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode material 108 may include a stack of a plurality of gate electrode materials, where zero or more materials of the stack are workfunction (WF) materials and at least one material of the stack is a fill metal layer. Further materials/layers may be included next to the gate electrode material 108 for other purposes, such as to act as a diffusion barrier layer or/and an adhesion layer.

In some embodiments, the gate insulator material 112 may include one or more high-k dielectrics including any of the materials discussed herein with reference to the insulator material that may surround portions of the transistor 110. In some embodiments, an annealing process may be carried out on the gate insulator material 112 during fabricate of the transistor 110 to improve the quality of the gate insulator material 112. The gate insulator material 112 may have a thickness that may, in some embodiments, be between about 0.5 nanometers and 3 nanometers, including all values and ranges therein (e.g., between about 1 and 3 nanometers, or between about 1 and 2 nanometers). In some embodiments, the gate stack 106 may be surrounded by a gate spacer, not shown in FIG. 1. Such a gate spacer would be configured to provide separation between the gate stack 106 and S/D contacts of the transistor 110 and could be made of a low-k dielectric material, some examples of which have been provided above.

Turning to the S/D regions 114 of the transistor 110, in some embodiments, the S/D regions may be highly doped, e.g., with dopant concentrations of about 10²¹ cm⁻³, in order to advantageously form Ohmic contacts with the respective S/D contacts (not shown in FIG. 1), although these regions may also have lower dopant concentrations and may form Schottky contacts in some implementations. Irrespective of the exact doping levels, the S/D regions of a transistor are the regions having dopant concentration higher than in other regions, e.g., higher than a dopant concentration in the transistor channel (i.e., in a channel material extending between the first S/D region 114-1 and the second S/D region 114-2), and, therefore, may be referred to as “highly doped” (HD) regions. Even when doped to realize threshold voltage tuning as described herein, the channel portions of transistors typically include semiconductor materials with doping concentrations significantly smaller than those of the S/D regions 114.

The S/D regions 114 of the transistor 110 may generally be formed using either an implantation/diffusion process or an etching/deposition process. In the former process, dopants such as boron, aluminum, antimony, phosphorous, or arsenic may be ion-implanted into the nanoribbon 104 to form the source and drain regions. An annealing process that activates the dopants and causes them to diffuse further into the nanoribbon 104 may follow the ion implantation process. In the latter process, portions of the nanoribbon 104 may first be etched to form recesses at the locations of the future S/D regions 114. An epitaxial deposition process may then be carried out to fill the recesses with material that is used to fabricate the S/D regions 114. In some implementations, the S/D regions 114 may be fabricated using a silicon alloy such as silicon germanium or silicon carbide. In some implementations, the epitaxially deposited silicon alloy may be doped in situ with dopants such as boron, arsenic, or phosphorous. In further embodiments, the S/D regions 114 may be formed using one or more alternate semiconductor materials such as germanium or a group Ill-V material or alloy. And in further embodiments, one or more layers of metal and/or metal alloys may be used to form the S/D regions 114. In some embodiments, a distance between the first and second S/D regions 114 (i.e., a dimension measured along the longitudinal axis 120 of the nanoribbon 104) may be between about 5 and 40 nanometers, including all values and ranges therein (e.g., between about 22 and 35 nanometers, or between about 20 and 30 nanometers).

The IC structure 100 shown in FIG. 1, as well as IC structures shown in other drawings of the present disclosure, is intended to show relative arrangements of some of the components therein, and the IC structure 100, or portions thereof, may include other components that are not illustrated (e.g., electrical contacts to the S/D regions 114 of the transistor 110). For example, although not specifically illustrated in FIG. 1, at least portions of the transistor 110 may be surrounded in an insulator material, such as any suitable interlayer dielectric (ILD) material. In some embodiments, such an insulator material may be a high-k dielectric including elements such as hafnium, silicon, oxygen, titanium, tantalum, lanthanum, aluminum, zirconium, barium, strontium, yttrium, lead, scandium, niobium, and zinc. Examples of high-k materials that may be used for this purpose may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In other embodiments, the insulator material surrounding portions of the transistor 110 may be a low-k dielectric material. Some examples of low-k dielectric materials include, but are not limited to, silicon dioxide, carbon-doped oxide, silicon nitride, organic polymers such as perfluorocyclobutane or polytetrafluoroethylene, fused silica glass (FSG), and organosilicates such as silsesquioxane, siloxane, or organosilicate glass. In another example, although not specifically illustrated in FIG. 1, a solid dielectric spacer may be provided between a first S/D contact (which may also be referred to as a “first S/D electrode”) coupled to a first S/D region 114-1 of the transistor 110 and the gate stack 106 as well as between a second S/D contact (which may also be referred to as a “second S/D electrode”) coupled to a second S/D region 114-2 of the transistor 110 and the gate stack 106 in order to provide electrical isolation between the source, gate, and drain electrodes. Embodiments of the present disclosure aim to replace at least portions of such a dielectric spacer with air, to provide IC structures with air gap insulation in place of gate spacers.

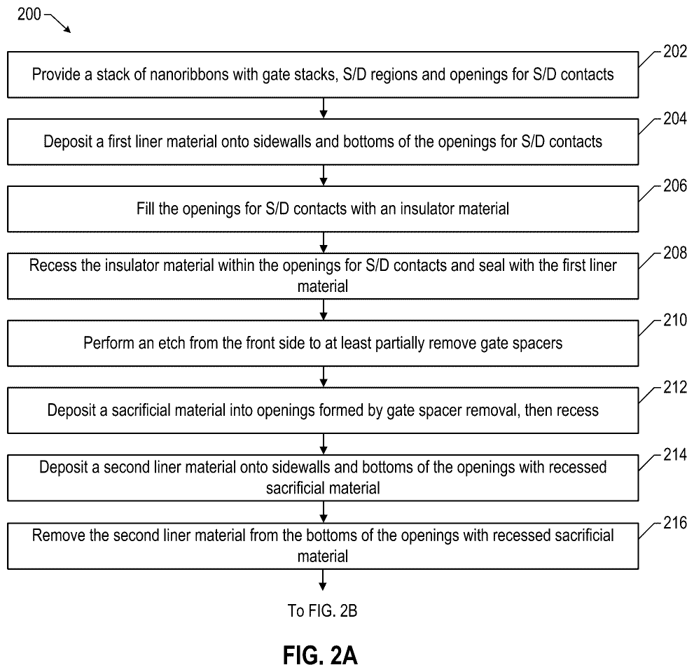

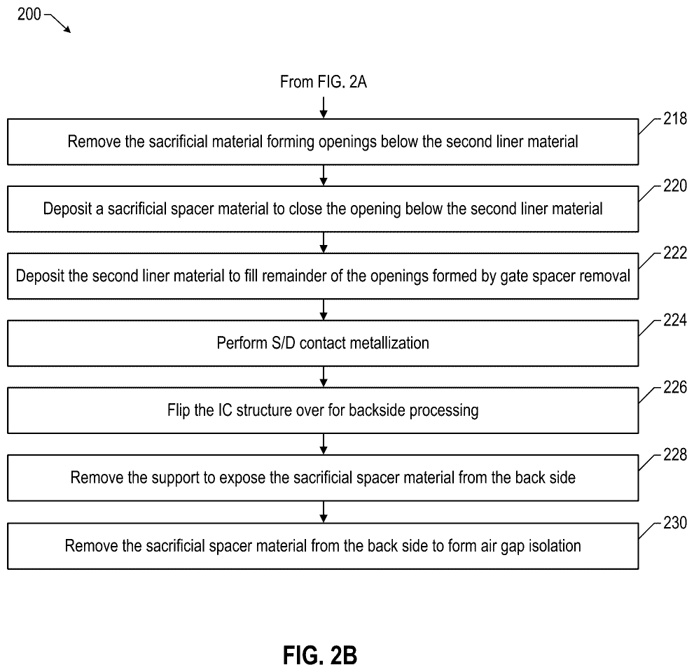

FIGS. 2A-2B is a flow diagram of an example method 200 for fabricating an IC structure with air gap insulation in place of gate spacers, in accordance with some embodiments. FIGS. 3A-3R provide cross-sectional side views at various stages in the fabrication of an example IC structure according to the method of FIGS. 2A-2B, in accordance with some embodiments. Most of FIGS. 3A-3R illustrate a cross-sectional side view of a given IC structure in the y-z plane of the coordinate system 105 along the axis 120 of FIG. 1, but a few illustrate a cross-sectional side view along the axis 121 of FIG. 1. In particular, FIGS. 3A-3M, 3O, and 3Q illustrate cross-sectional side views of IC structures in the y-z plane of the coordinate system 105 along the axis 120 of FIG. 1, while FIGS. 3N, 3P and 3R illustrate cross-sectional side views of IC structures in the y-z plane of the coordinate system 105 along the axis 121 of FIG. 1. A number of elements referred to in the description of FIGS. 3A-3R with reference numerals are illustrated in these drawings with different patterns, with a legend showing the correspondence between the reference numerals and patterns being provided at the bottom of each drawing page containing FIGS. 3A-3R. For example, the legend illustrates that FIGS. 3A-3R use different patterns to show a support 302, nanoribbons 304, a gate electrode material 308, a gate insulator material 312, and so on.

Although the operations of the method 200 are illustrated once each and in a particular order, the operations may be performed in any suitable order and repeated as desired. For example, one or more operations may be performed in parallel to fabricate multiple IC structures with air gap insulation in place of gate spacers substantially simultaneously. In another example, the operations may be performed in a different order to reflect the structure of an IC device in which an IC structure with air gap insulation in place of gate spacers will be implemented.

In addition, the example fabricating method 200 may include other operations not specifically shown in FIGS. 2A-2B, such as various cleaning or planarization operations as known in the art. For example, in some embodiments, a support 302, as well as layers of various other materials subsequently deposited thereon, may be cleaned prior to, after, or during any of the processes of the method 200 described herein, e.g., to remove oxides, surface-bound organic and metallic contaminants, as well as subsurface contamination. In some embodiments, cleaning may be carried out using e.g., a chemical solutions (such as peroxide), and/or with ultraviolet (UV) radiation combined with ozone, and/or oxidizing the surface (e.g., using thermal oxidation) then removing the oxide (e.g., using hydrofluoric acid (HF)). In another example, the intermediate IC structures described herein may be planarized prior to, after, or during any of the processes of the method 200 described herein, e.g., to remove overburden or excess materials. In some embodiments, planarization may be carried out using either wet or dry planarization processes, e.g., planarization be a chemical mechanical planarization (CMP), which may be understood as a process that utilizes a polishing surface, an abrasive and a slurry to remove the overburden and planarize the surface.

The method 200 may begin with a process 202 that includes providing a stack of released nanoribbons over a support and forming a gate stack, S/D regions and openings for S/D contacts. An IC structure 352 of FIG. 3A illustrates an example result of the process 202. The IC structure 352 illustrates a support 302, a stack of released nanoribbons 304 over the support 302, a gate stack 306 with a gate electrode material 308 and a gate insulator material 312, and S/D regions 314. The support 302, the nanoribbons 304, the gate stacks 306, the gate electrode material 308, the gate insulator material 312, and the S/D regions 314 may be examples of, respectively, the support 102, the nanoribbons 104, the gate stacks 106, the gate electrode material 108, the gate insulator material 112, and the S/D regions 114 described above.

FIG. 3A illustrates that a plurality of nanoribbons 304 may be stacked above one another. FIG. 3A and subsequent drawings illustrate four nanoribbons 304 in a stack, but, in other embodiments, a stack of nanoribbons 304 may include any other number of two or more nanoribbons 304. The material composition of different stacks of nanoribbons 304 may be different depending on whether the stacks are to implement NMOS or PMOS transistors, in line with the descriptions provided above. The nanoribbons 304 are “released” in that openings were previously formed around channel portions of the nanoribbons 304, in which openings the gate insulator materials 312 and the gate electrode materials 308 as described above are subsequently provided. FIG. 3A also illustrates gate spacers 322 surrounding each of the gate stacks 306. The gate spacers 322 may be configured to provide separation between the gate stack 306 and future S/D contacts of transistors 110 provided along the stack of the nanoribbons 304 and could be made of a low-k dielectric material, some examples of which have been provided above. As a result of performing the method 200, some or all of the gate spacers 322 between the gate contacts and S/D contacts may be removed, as will be shown in subsequent drawings. FIG. 3A further illustrates an electrically conductive material 324 that may be provided over the gate electrode material 312 and may serve as a gate line for providing electrical conductivity to the gate of the transistor based on the stack of nanoribbons 304 (e.g., by being in electrically conductive contact with the gate electrode material 312). The electrically conductive material 324 may include any suitable electrically conductive material, which may include an alloy or a stack of multiple electrically conductive materials. In some embodiments, such electrically conductive materials may include one or more metals or metal alloys, with metals such as ruthenium, palladium, platinum, cobalt, nickel, hafnium, zirconium, titanium, tantalum, and aluminum. In some embodiments, such electrically conductive materials may include one or more electrically conductive alloys oxides or carbides of one or more metals.

FIG. 3A illustrates S/D regions 314 extending through the stack of nanoribbons 304, as well as an insulator material 316 to electrically insulate/separate the S/D regions 314 from the gate electrode material 312 of the gate stacks 306 and from the support 302. Portions of the insulator material 316 extending from the respective side of the S/D regions 314 into the openings between the nanoribbons 304 where the gate stacks 306 are provided may be referred to as “dimples” 317. In other embodiments, shape of the dimples 317 may be different from that shown in FIG. 3A, as long as the dimples 317 of the insulator material 316 provide electrical isolation between the S/D regions 314 and the gate electrode material 312. The insulator material 316 may include any suitable insulator material, e.g., one or more materials described with reference to the ILD materials.

The stack of released nanoribbons 304 provided over the support 302, the gate stacks 306, and the S/D regions 314 may be formed according to any of the techniques known in the art. FIG. 3A further illustrates openings 326, individually labeled as openings 326-1 and 326-2, provided above the stack of nanoribbons 304 in order to expose the S/D regions 314.

The method 200 may then proceed with a process 204, in which a first liner material is deposited onto sidewalls and bottom of the openings for S/D contacts of the IC structure 352. An IC structure 354 of FIG. 3B illustrates an example result of the process 204. As shown in FIG. 3B, a first liner material 330 may line sidewalls and bottom of the openings 326. The first liner material 330 may include any material that is sufficiently etch selective with respect to the etchants used in the process 210. As known in the art, two materials are said to be “etch-selective” (or said to have “sufficient etch selectivity”) with respect to one another when etchants used to etch one material do not substantially etch the other, enabling selective etching of one material but not the other. For example, in some embodiments, the first liner material 330 may include aluminum and oxygen (e.g., the first liner material 330 may be aluminum oxide). The first liner material 330 may be deposited using any suitable deposition technique, such as any suitable conformal deposition technique such as atomic layer deposition (ALD). A thickness of the first liner material 330 may be between about 1 nanometer and about 10 nanometers in some embodiments, including all values and ranges therein, e.g., between about 1 nanometer and 8 nanometers, or between about 1 nanometer and 5 nanometers.

In a process 206 of the method 200, the openings for S/D contacts lined with the first liner material may be filled with an insulator material. An IC structure 356 of FIG. 3C illustrates an example result of the process 206. As shown in FIG. 3C, the openings 326 lined with the first liner material 330 may be filled with an insulator material 332. The insulator material 332 may include any suitable insulator material, e.g., one or more materials described with reference to the ILD materials and may be deposited in the process 206 using techniques such as ALD or chemical vapor deposition (CVD).

The method 200 may then proceed with a process 208, in which the insulator material in the openings for S/D contacts of the IC structure 354 is recessed and covered with another layer of the first liner material. An IC structure 358 of FIG. 3D illustrates an example result of the process 208. As shown in FIG. 3D, the insulator material 332 is recessed so that it may be covered with another layer of the first liner material 330 at the top of the openings 326. In this manner, the insulator material 332 may be completely encapsulated on all sides by the first liner material 330. In some embodiments, the depth of the recess of the insulator material 332 may be between about 1 nanometer and about 10 nanometers in some embodiments, including all values and ranges therein, e.g., between about 1 nanometer and 8 nanometers, or between about 1 nanometer and 5 nanometers. In some embodiments, material compositions of the first liner material 330 deposited in the process 204 and the first liner material 330 deposited in the process 208 may be the same, but, in other embodiments, the material compositions may be different, as long as the first liner material 330 deposited in the process 208 is also sufficiently etch-selective with respect to the etchants used in the process 210.

The method 200 may further include a process 210, in which an etch process is performed from the front side of the IC structure 358 to remove some or all of the gate spacers, thus forming openings between the gate contacts and future S/D contacts. An IC structure 360 of FIG. 3E illustrates an example result of the process 210. FIG. 3E and subsequent drawings illustrate that the gate spacers 322 are removed entirely, forming openings 328 (only one of which is individually labeled), but, in other embodiments, some of the gate spacers 322 may remain in the openings 328. Any suitable etching technique, e.g., a dry etch, such as e.g., radio frequency (RF) reactive ion etch (RIE) or inductively coupled plasma (ICP) RIE could be used to remove the gate spacers 322 to form the openings 328. In some embodiments, the etch performed in the process 210 may include an anisotropic etch, using etchants in a form of e.g., chemically active ionized gas (i.e., plasma) using e.g., bromine (Br) and chloride (CI) based chemistries. In some embodiments, during the etch of the process 210, the IC structure may be heated to elevated temperatures, e.g., to temperatures between about room temperature and 200 degrees Celsius, including all values and ranges therein, to promote that byproducts of the etch are made sufficiently volatile to be removed from the surface. As shown in FIG. 3E, the insulator material 332 may remain intact because it is protected from the etch of the process 210 by the first liner material 330 that encapsulates it. Furthermore, the electrically conductive materials of the gate contact (e.g., the electrically conductive material 324 and the gate electrode material 308) may also be sufficiently etch-selective with respect to the etchants used in the process 210, although, in some embodiments, at least the top portions of the electrically conductive materials of the gate contact may be partially etched in the process 210, and may result in a rounded profile. The rounded profile is shown in FIG. 3E with a dashed contour 333. Such rounding of the gate contact would then be indicative of the use of the method 200.

In a process 212 of the method 200, the openings formed by at least partial removal of the gate spacers may be filled with a sacrificial material, followed by a recess of the sacrificial material. An IC structure 362 of FIG. 3F illustrates an example result of the process 212. As shown in FIG. 3F, the openings 328 may be filled with a sacrificial material 334, and the sacrificial material 334 may then be recessed. In various embodiments, the sacrificial material 334 may include any suitable material that may later be removed from the high aspect ratio openings 328. For example, the sacrificial material 334 may be any suitable organic material, e.g., any suitable carbon-based material, that may later be removed by ashing. In some embodiments, the depth of the recess of the sacrificial material 334 may be between about 1 nanometer and about 10 nanometers in some embodiments, including all values and ranges therein, e.g., between about 1 nanometer and 8 nanometers, or between about 1 nanometer and 5 nanometers.

The method 200 may then proceed with a process 214, in which a second liner material is deposited onto sidewalls and bottom of the openings formed by recesses in the sacrificial material deposited into openings from the removal of gate spacers. An IC structure 364 of FIG. 3G illustrates an example result of the process 214. As shown in FIG. 3G, a second liner material 336 may line sidewalls and bottom of the openings 328 filled partially with the sacrificial material 334. The second liner material 336 may include any material that is sufficiently etch selective with respect to the etchants used to remove the sacrificial material 334 in the process 218. For example, in some embodiments, the second liner material 336 may include silicon and nitrogen (e.g., the second liner material 336 may be silicon nitride). The second liner material 336 may be deposited using any suitable deposition technique, such as any suitable conformal deposition technique such as ALD. A thickness of the second liner material 336 may be between about 1 nanometer and about 10 nanometers in some embodiments, including all values and ranges therein, e.g., between about 1 nanometer and 5 nanometers, or between about 1 nanometer and 3 nanometers.

The method 200 may further include a process 216, in which an etch process is performed from the front side of the IC structure 364 to remove the second liner material from the bottoms of the openings filled with the recessed sacrificial material. An IC structure 366 of FIG. 3H illustrates an example result of the process 216. As shown in FIG. 3H, as a result of performing the process 216, the sacrificial material 334 may be exposed at the bottoms of the openings 328, where the second liner material 336 has been removed. Any suitable etching technique, e.g., any of those described with respect to the process 210, may be used in the process 216 to remove the second liner material 336 from the bottoms of the openings. In some embodiments, during the etch of the process 216, the IC structure may be heated to elevated temperatures, e.g., to temperatures between about room temperature and 200 degrees Celsius, including all values and ranges therein, to promote that byproducts of the etch are made sufficiently volatile to be removed from the surface.

In a process 218 of the method 200, the sacrificial material may be removed, thus forming openings below the second liner material at the top of the openings 328. An IC structure 368 of FIG. 3I illustrates an example result of the process 218. A technique such as ashing may be used in the process 218 to remove the sacrificial material 334.

The method 200 may then proceed with a process 220, in which a sacrificial spacer material is deposited into the openings formed by removal of the sacrificial material. An IC structure 370 of FIG. 3J illustrates an example result of the process 220. As shown in FIG. 3B, a sacrificial spacer material 338 may line sidewalls and bottom of the openings 328 below the second liner material 336, but not fill the openings 328 completely. This is acceptable, as long as the sacrificial spacer material 338 pinches at the top (i.e., closes so that the openings 328 are encapsulated by it). In other embodiments, the sacrificial spacer material 338 may fill the openings 328 completely. The sacrificial spacer material 338 may include any material that is sufficiently-etch selective with respect to the etchants used in subsequent processing steps where S/D contacts are formed. Furthermore, the sacrificial spacer material 338 may include any material that can be removed by wet etch tat is selective to other materials in the back end such as gate metals, ILD, etc. For example, in some embodiments, the sacrificial spacer material 338 may include aluminum and oxygen (e.g., the sacrificial spacer material 338 may be aluminum oxide). The sacrificial spacer material 338 may be deposited using any suitable deposition technique, such as ALD or CVD.

The method 200 may further include a process 222, in which the remainder of the openings 328 are filled with the second liner material, followed by polishing of the second liner material to expose the top of the first liner material 330 in the openings for S/D contacts. An IC structure 372 of FIG. 3K illustrates an example result of the process 222. As shown in FIG. 3K, the second liner material 336 now closes the remainder of the openings 328, but elsewhere the second liner material 336 has been polished to expose the first liner material 330 encapsulating the openings 326. Any of the deposition techniques described above may be used to deposit the second liner material 336 in the process 222. In some embodiments, material compositions of the second liner material 336 deposited in the process 214 and the second liner material 336 deposited in the process 222 may be the same, but, in other embodiments, the material compositions may be different.

The method 200 may then proceed with a process 224, in which the openings for S/D contacts are opened again and filled with one or more electrically conductive material to form S/D contacts. An IC structure 374 of FIG. 3L illustrates an example result of the process 224. As shown in FIG. 3L, the first liner material 330 and the insulator material 332 are removed from the openings 326, and the openings 326 are then filled with an electrically conductive material 342. In some embodiments, prior to depositing the electrically conductive material 342 into the openings 326, a layer of an interface material may be deposited at the bottom of the openings 326. In some embodiments, the interface material may be deposited directly onto the material of the S/D regions 314. Subsequently, the interface material may interact with the material of S/D regions 314, forming an interface 340 at the bottom of the openings 326. For example, if the interface material is titanium and the S/D regions 314 included silicon, then the interface 340 may be a layer of titanium silicide. Providing the interface 340 at the bottom of the openings 326 may help improve conductivity of S/D contacts, e.g., by reducing contact resistance. The electrically conductive material 342 may include any suitable electrically conductive material, such as any of those described above, and may be deposited in the process 224 using a technique such as ALD, CVD, plasma enhanced CVD (PECVD), or/and physical vapor deposition (PVD) processes such as sputter. The electrically conductive material 342 will form contacts to S/D regions 314 and, therefore, the process 224 may be referred to as “S/D contact metallization.”

In a process 226, the IC structure of the previous process is flipped over so that it is ready for backside processing. An IC structure 376 of FIGS. 3M-3N illustrates an example result of the process 226. The IC structure 376 of FIG. 3M is substantially the same as the IC structure 372 of FIG. 3L but shown upside down. The IC structure 376 shown in FIG. 3N is the same IC structure as shown in FIG. 3M, but with the cross-section taken in a direction perpendicular to the support 302 but along the axis 121 of FIG. 1.

The method 200 may then proceed with a process 228, in which the support is removed from the back side of the IC structure 376 to expose the sacrificial spacer material 338. An IC structure 378 of FIGS. 3O-3P illustrates an example result of the process 228, in cross-sections along, respectively, axis 120 and axis 121 of FIG. 1. The IC structure 378 of FIG. 3O is substantially the same as the IC structure 376 of FIG. 3M but with the support 302 removed. The IC structure 378 shown in FIG. 3P is the same IC structure as shown in FIG. 3N, but also with the support 302 removed and this illustration shows how removal of the support exposes the sacrificial spacer material 338 that was deposited in the process 220. The support 302 may be removed from the back side by a process such as grinding.

The method 200 may further include a process 230, in which the sacrificial spacer material 338 may be removed through the openings that were created by removing the support 302 and exposing the sacrificial spacer material 338 in the process 228. An IC structure 380 of FIGS. 3Q-3R illustrates an example result of the process 230, in cross-sections along, respectively, axis 120 and axis 121 of FIG. 1. The IC structure 380 of FIG. 3Q is substantially the same as the IC structure 376 of FIG. 3O but with the sacrificial spacer material 338 removed. The IC structure 380 shown in FIG. 3R is the same IC structure as shown in FIG. 3P, but also with the sacrificial spacer material 338 removed, thus forming openings 344 (which may also be referred to as “gaps”) that provide air gap isolation between the electrically conductive materials of the gate contact (e.g., the electrically conductive material 324 and the and the gate electrode material 308) and the electrically conductive materials of the S/D contacts on either side of the gate contact (e.g., the electrically conductive material 342). A wet etch process may be used in the process 230 to remove the sacrificial spacer material 338 without substantially etching other materials in its vicinity. Using the sacrificial spacer material 338 and the wet etch process improves selectivity with respect to nearby structures such as materials of the S/D regions 314 or the gate electrode material 308.

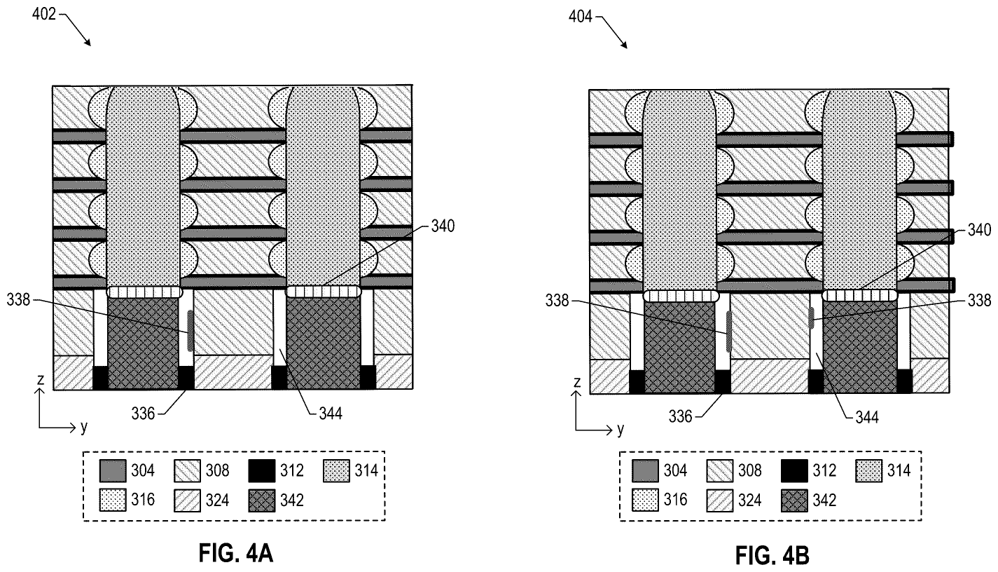

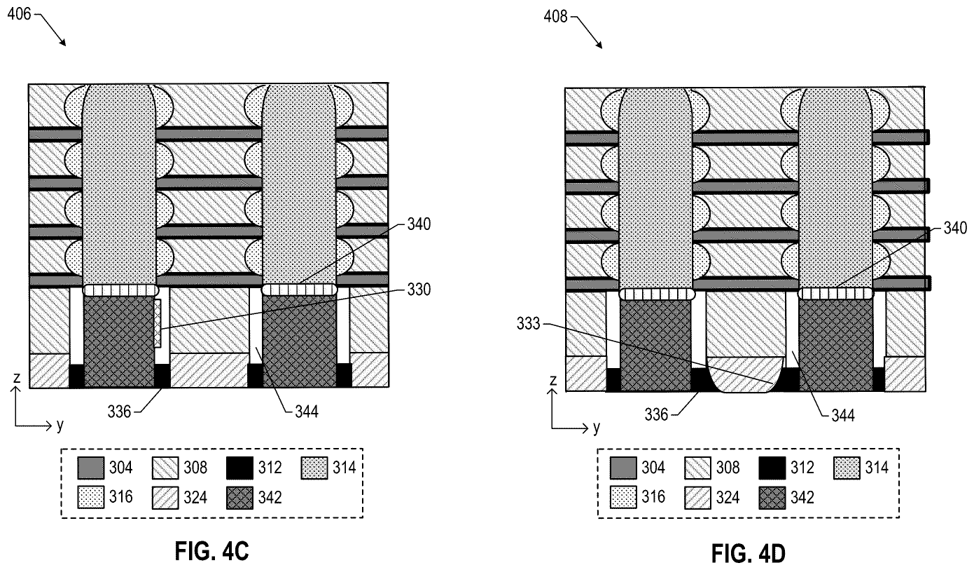

Performing the method 200 may result in several features in the final IC structures that are characteristic of the use of the method 200. For example, one such feature is illustrated in an IC structure 402 shown in FIG. 4A. The IC structure 402 is substantially the same as the IC structure 380 shown in FIG. 3Q (i.e., also illustrating a cross-sectional side view along the axis 120 of FIG. 1), but showing that, in some embodiments, a defect level traces of the sacrificial spacer material 338 may remain on at least portions of some of the sidewalls of the openings 344. Such traces may be relatively thin, e.g., having a thickness (e.g., a dimension measured substantially perpendicular to the sidewall of the opening 344 on which a trace is provided) below about 2 nanometers, e.g., between about 1 nanometers and 1.6 nanometers, but they would still be detectable in the final IC structures. In some embodiments, defect level traces of the sacrificial spacer material 338 remaining on at least portions of some of the sidewalls of the openings 344 may not be symmetric, as illustrated in FIG. 4B. FIG. 4B illustrates an IC structure 404 that is substantially the same as the IC structure 402 shown in FIG. 4A but showing two instances of example defect level traces of the sacrificial spacer material 338. In some embodiments, defect level traces of the sacrificial spacer material 338 remaining on at least portions of some of the sidewalls of the openings 344 may be on sidewall of the gate contacts, as shown in FIGS. 4A-4B, i.e., closer to a gate contact/structure formed by the gate electrode material 308 and the electrically conductive material 324 than to a S/D contact structure formed by the electrically conductive material 342. In some embodiments, a defect level trace of the sacrificial spacer material 338 may be a liner on a sidewall of the gate contact of the opening 344, such that the liner of the sacrificial spacer material 338 may be in contact with the electrically conductive material 324 or/and in contact with the gate electrode material 308.

Another feature characteristic of the use of the method 200 is shown in an IC structure 406 shown in FIG. 4C. Similar to the IC structures 402 and 404, the IC structure 406 is substantially the same as the IC structure 380 shown in FIG. 3Q, but showing that, in some embodiments, a defect level traces of the first liner material 330 may remain on at least portions of some of the sidewalls of the openings 344. Such traces may be relatively thin, e.g., having a thickness (e.g., a dimension measured substantially perpendicular to the sidewall of the opening 344 on which a trace is provided) below about 2 nanometers, e.g., between about 1 nanometers and 1.6 nanometers, but they would still be detectable in the final IC structures. In some embodiments, defect level traces of the first liner material 330 remaining on at least portions of some of the sidewalls of the openings 344 may be on sidewall of the S/D contacts, as shown in FIG. 4C, i.e., closer to a S/D contact structure formed by the electrically conductive material 342 than to a gate contact/structure formed by the gate electrode material 308 and the electrically conductive material 324. In some embodiments, a defect level trace of the first liner material 330 may be a liner on a sidewall of the S/D contact of the opening 344, such that the liner of the first liner material 330 may be in contact with the electrically conductive material 342.

Yet another feature characteristic of the use of the method 200 is shown in an IC structure 408 shown in FIG. 4D. Similar to the IC structures 402, 404, and 406, the IC structure 408 is substantially the same as the IC structure 380 shown in FIG. 3Q but showing that, in some embodiments, the top (if looking at the IC structure 408 from the front side) of the gate contact (e.g., the electrically conductive material 324) may be rounded, e.g., in accordance with the dashed contour 333 shown in FIG. 3E and explained above.

Also characteristic of the use of the method 200 is that the second liner material 336 may at least partially close the openings 344 between the gate structure and the contact structure, e.g., the opening 344 may be between the channel region and the second liner material 336, as shown in each of FIGS. 4A-4D. In some embodiments, a thickness of the second liner material 336 that is at least partially closing the openings 344 (e.g., a dimension measured along the z-axis of the coordinate system 105) may be between about 1 nanometer and 8 nanometers.

In various further embodiments, an IC structure fabricated using the method 200 may include any combination of the characteristic features as shown in FIGS. 4A-4D.

IC structures with air gap insulation in place of gate spacers as described herein (e.g., as described with reference to FIGS. 1-4) may be used to implement any suitable components. For example, in various embodiments, IC structures described herein may be part of one or more of: a central processing unit, a memory device (e.g., a high-bandwidth memory device), a memory cell, a logic circuit, input/output circuitry, a field programmable gate array (FPGA) component such as an FPGA transceiver or an FPGA logic, a power delivery circuitry, an amplifier (e.g., a Ill-V amplifier), Peripheral Component Interconnect Express (PCIE) circuitry, Double Data Rate (DDR) transfer circuitry, a computing device (e.g., a wearable or a handheld computing device), etc.

The IC structures with air gap insulation in place of gate spacers disclosed herein, e.g., the IC structure 380, any of the IC structures shown in FIG. 4A-4D, or any combination of such IC structures, may be included in any suitable electronic component. FIGS. 5-9 illustrate various examples of apparatuses that may include one or more IC structures disclosed herein.

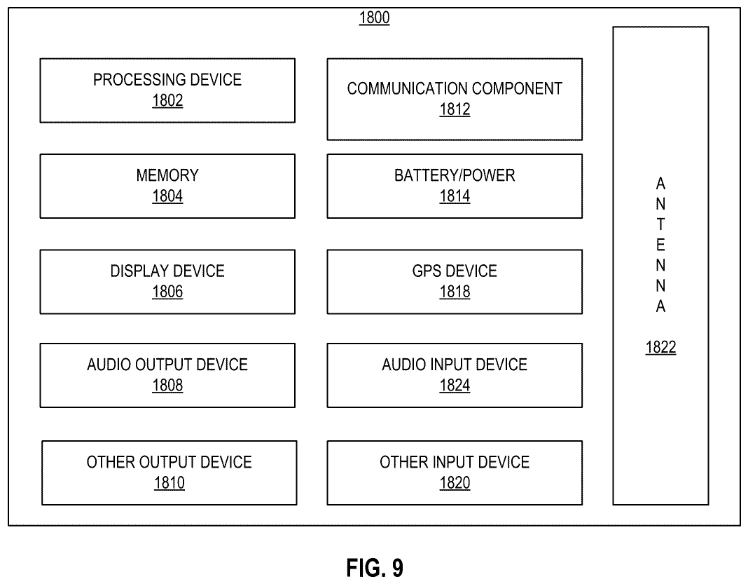

FIG. 5 is a top view of a wafer 1500 and dies 1502 that may include one or more IC structures with air gap insulation in place of gate spacers in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. The die 1502 may include one or more of the IC structure 380, any of the IC structures shown in FIG. 4A-4D, or any combination of such IC structures, and/or supporting circuitry to route electrical signals to the transistors of these IC structures, as well as any other IC components. In some embodiments, the wafer 1500 or the die 1502 may include a memory device (e.g., a random-access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 9) or other logic that is configured to store information in the memory devices or execute instructions stored in the memory array.

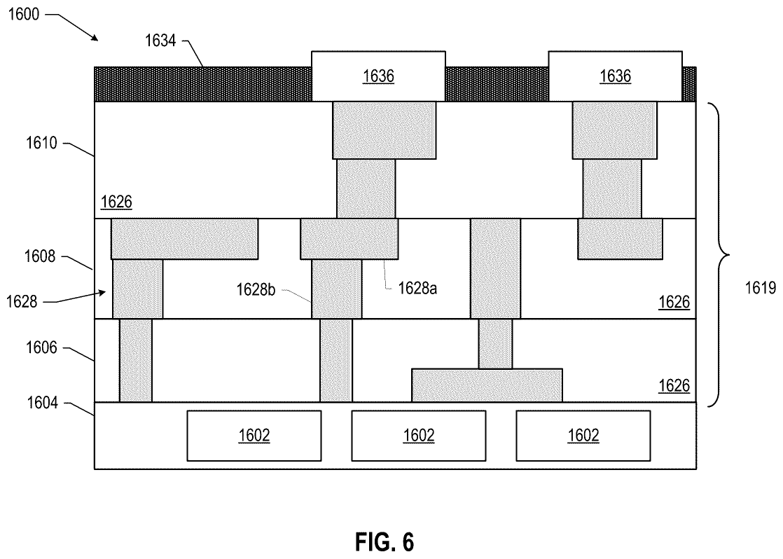

FIG. 6 is a side, cross-sectional view of an IC device 1600 that may include one or more IC structures with air gap insulation in place of gate spacers in accordance with any of the embodiments disclosed herein. One or more of the IC devices 1600 may be included in one or more dies 1502 (FIG. 5). The IC device 1600 may include a device region 1604 including one or more IC structures 1602, where any of the IC structures 1602 may include any of the IC structures with air gap insulation in place of gate spacers, disclosed herein, e.g., the IC structure 380, any of the IC structures shown in FIG. 4A-4D, or any combination of such IC structures. The device region 1604 may further include electrical contacts to the gate and S/D contacts of the transistors included in the device region 1604.

Electrical signals, such as power and/or input/output (I/O) signals, may be routed to and/or from the devices (e.g., the transistors) of the device region 1604 through one or more interconnect layers disposed on the device region 1604 (illustrated in FIG. 6 as interconnect layers 1606, 1608, and 1610). For example, electrically conductive features of the device region 1604 (e.g., the gate electrode materials 108, the electrically conductive materials 342, and the electrically conductive materials 324 of the IC structures 1602) may be electrically coupled with the interconnect structures 1628 of the interconnect layers 1606, 1608, and 1610. The one or more interconnect layers 1606, 1608, and 1610 may form a metallization stack (also referred to as an “ILD stack”) 1619 of the IC device 1600.

The interconnect structures 1628 may be arranged within the interconnect layers 1606, 1608, and 1610 to route electrical signals according to a wide variety of designs (in particular, the arrangement is not limited to the particular configuration of interconnect structures 1628 depicted in FIG. 6). Although a particular number of interconnect layers 1606, 1608, and 1610 is depicted in FIG. 6, embodiments of the present disclosure include IC structures having more or fewer interconnect layers than depicted.

In some embodiments, the interconnect structures 1628 may include lines 1628a and/or vias 1628b filled with an electrically conductive material such as a metal. The lines 1628a may be arranged to route electrical signals in a direction of a plane that is substantially parallel with a surface of the support 102 upon which the device region 1604 is formed. For example, the lines 1628a may route electrical signals in a direction in and out of the page from the perspective of FIG. 6. The vias 1628b may be arranged to route electrical signals in a direction of a plane that is substantially perpendicular to the surface of the support 102 upon which the device region 1604 is formed. In some embodiments, the vias 1628b may electrically couple lines 1628a of different interconnect layers 1606, 1608, and 1610 together.

The interconnect layers 1606, 1608, and 1610 may include a dielectric material 1626 disposed between the interconnect structures 1628, as shown in FIG. 6. In some embodiments, the dielectric material 1626 disposed between the interconnect structures 1628 in different ones of the interconnect layers 1606, 1608, and 1610 may have different compositions; in other embodiments, the composition of the dielectric material 1626 between different interconnect layers 1606, 1608, and 1610 may be the same.

A first interconnect layer 1606 may be formed above the device region 1604. In some embodiments, the first interconnect layer 1606 may include lines 1628a and/or vias 1628b, as shown. The lines 1628a of the first interconnect layer 1606 may be coupled with contacts (e.g., contacts to the S/D regions 114 of the IC structures with air gap insulation in place of gate spacers) of the device region 1604.

A second interconnect layer 1608 may be formed above the first interconnect layer 1606. In some embodiments, the second interconnect layer 1608 may include vias 1628b to couple the lines 1628a of the second interconnect layer 1608 with the lines 1628a of the first interconnect layer 1606. Although the lines 1628a and the vias 1628b are structurally delineated with a line within each interconnect layer (e.g., within the second interconnect layer 1608) for the sake of clarity, the lines 1628a and the vias 1628b may be structurally and/or materially contiguous (e.g., simultaneously filled during a dual-damascene process) in some embodiments.

A third interconnect layer 1610 (and additional interconnect layers, as desired) may be formed in succession on the second interconnect layer 1608 according to similar techniques and configurations described in connection with the second interconnect layer 1608 or the first interconnect layer 1606. In some embodiments, the interconnect layers that are “higher up” in the metallization stack 1619 in the IC device 1600 (i.e., farther away from the device region 1604) may be thicker.

The IC device 1600 may include a solder resist material 1634 (e.g., polyimide or similar material) and one or more conductive contacts 1636 formed on the interconnect layers 1606, 1608, and 1610. In FIG. 6, the conductive contacts 1636 are illustrated as taking the form of bond pads. The conductive contacts 1636 may be electrically coupled with the interconnect structures 1628 and configured to route the electrical signals of the transistor(s) of the device region 1604 to other external devices. For example, solder bonds may be formed on the one or more conductive contacts 1636 to mechanically and/or electrically couple a chip including the IC device 1600 with another component (e.g., a circuit board). The IC device 1600 may include additional or alternate structures to route the electrical signals from the interconnect layers 1606, 1608, and 1610; for example, the conductive contacts 1636 may include other analogous features (e.g., posts) that route the electrical signals to external components.

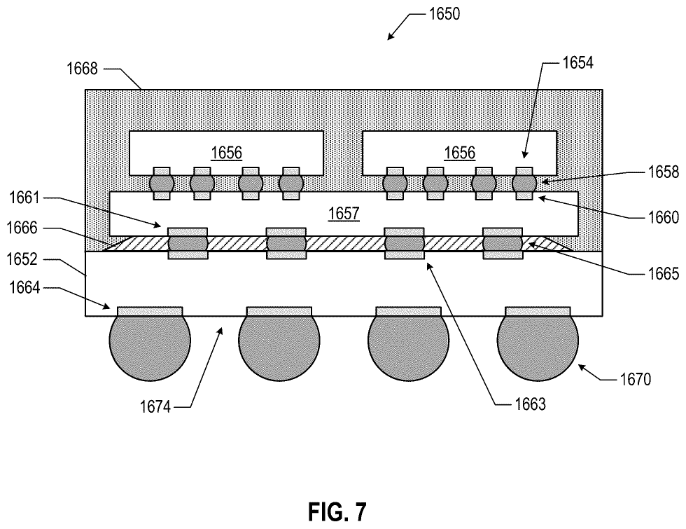

FIG. 7 is a side, cross-sectional view of an example IC package 1650 that may include one or more IC structures with air gap insulation in place of gate spacers in accordance with any of the embodiments disclosed herein. In some embodiments, the IC package 1650 may be a system-in-package (SiP).

The package substrate 1652 may be formed of a dielectric material (e.g., a ceramic, a buildup film, an epoxy film having filler particles therein, glass, an organic material, an inorganic material, combinations of organic and inorganic materials, embedded portions formed of different materials, etc.), and may have conductive pathways extending through the dielectric material between the face 1672 and the face 1674, or between different locations on the face 1672, and/or between different locations on the face 1674. These conductive pathways may take the form of any of the interconnects 1628 discussed above with reference to FIG. 6.

The package substrate 1652 may include conductive contacts 1663 that are coupled to conductive pathways (not shown) through the package substrate 1652, allowing circuitry within the dies 1656 and/or the interposer 1657 to electrically couple to various ones of the conductive contacts 1664 (or to devices included in the package substrate 1652, not shown).

The IC package 1650 may include an interposer 1657 coupled to the package substrate 1652 via conductive contacts 1661 of the interposer 1657, first-level interconnects 1665, and the conductive contacts 1663 of the package substrate 1652. The first-level interconnects 1665 illustrated in FIG. 7 are solder bumps, but any suitable first-level interconnects 1665 may be used. In some embodiments, no interposer 1657 may be included in the IC package 1650; instead, the dies 1656 may be coupled directly to the conductive contacts 1663 at the face 1672 by first-level interconnects 1665. More generally, one or more dies 1656 may be coupled to the package substrate 1652 via any suitable structure (e.g., a silicon bridge, an organic bridge, one or more waveguides, one or more interposers, wirebonds, etc.).

The IC package 1650 may include one or more dies 1656 coupled to the interposer 1657 via conductive contacts 1654 of the dies 1656, first-level interconnects 1658, and conductive contacts 1660 of the interposer 1657. The conductive contacts 1660 may be coupled to conductive pathways (not shown) through the interposer 1657, allowing circuitry within the dies 1656 to electrically couple to various ones of the conductive contacts 1661 (or to other devices included in the interposer 1657, not shown). The first-level interconnects 1658 illustrated in FIG. 7 are solder bumps, but any suitable first-level interconnects 1658 may be used. As used herein, a “conductive contact” may refer to a portion of conductive material (e.g., metal) serving as an interface between different components; conductive contacts may be recessed in, flush with, or extending away from a surface of a component, and may take any suitable form (e.g., a conductive pad or socket).

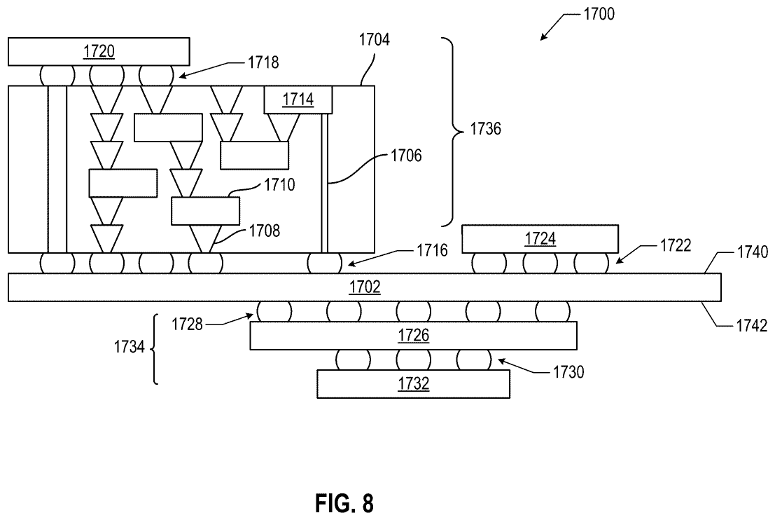

In some embodiments, an underfill material 1666 may be disposed between the package substrate 1652 and the interposer 1657 around the first-level interconnects 1665, and a mold compound 1668 may be disposed around the dies 1656 and the interposer 1657 and in contact with the package substrate 1652. In some embodiments, the underfill material 1666 may be the same as the mold compound 1668. Example materials that may be used for the underfill material 1666 and the mold compound 1668 are epoxy mold materials, as suitable. Second-level interconnects 1670 may be coupled to the conductive contacts 1664. The second-level interconnects 1670 illustrated in FIG. 7 are solder balls (e.g., for a ball grid array arrangement), but any suitable second-level interconnects 1670 may be used (e.g., pins in a pin grid array arrangement or lands in a land grid array arrangement). The second-level interconnects 1670 may be used to couple the IC package 1650 to another component, such as a circuit board (e.g., a motherboard), an interposer, or another IC package, as known in the art and as discussed below with reference to FIG. 8.

The dies 1656 may take the form of any of the embodiments of the die 1502 discussed herein (e.g., may include any of the embodiments of the IC device 1600). In embodiments in which the IC package 1650 includes multiple dies 1656, the IC package 1650 may be referred to as a multi-chip package (MCP). The dies 1656 may include circuitry to perform any desired functionality. For example, or more of the dies 1656 may be logic dies (e.g., silicon-based dies), and one or more of the dies 1656 may be memory dies (e.g., high-bandwidth memory).

Although the IC package 1650 illustrated in FIG. 7 is a flip chip package, other package architectures may be used. For example, the IC package 1650 may be a ball grid array (BGA) package, such as an embedded wafer-level ball grid array (eWLB) package. In another example, the IC package 1650 may be a wafer-level chip scale package (WLCSP) or a panel fanout (FO) package. Although two dies 1656 are illustrated in the IC package 1650 of FIG. 7, an IC package 1650 may include any desired number of dies 1656. An IC package 1650 may include additional passive components, such as surface-mount resistors, capacitors, and inductors disposed on the first face 1672 or the second face 1674 of the package substrate 1652, or on either face of the interposer 1657. More generally, an IC package 1650 may include any other active or passive components known in the art.

FIG. 8 is a side, cross-sectional view of an IC device assembly 1700 that may include one or more IC packages or other electronic components (e.g., a die) including one or more IC structures with air gap insulation in place of gate spacers in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any of the embodiments of the IC package 1650 discussed above with reference to FIG. 7 (e.g., may include one or more IC structures with air gap insulation in place of gate spacers).

In some embodiments, the circuit board 1702 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 8 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 8), male and female portions of a socket, an adhesive, an underfill material, and/or any other suitable electrical and/or mechanical coupling structure.

The package-on-interposer structure 1736 may include an IC package 1720 coupled to a package interposer 1704 by coupling components 1718. The coupling components 1718 may take any suitable form for the application, such as the forms discussed above with reference to the coupling components 1716. Although a single IC package 1720 is shown in FIG. 8, multiple IC packages may be coupled to the package interposer 1704; indeed, additional interposers may be coupled to the package interposer 1704. The package interposer 1704 may provide an intervening substrate used to bridge the circuit board 1702 and the IC package 1720. The IC package 1720 may be or include, for example, a die (the die 1502 of FIG. 5), an IC device (e.g., the IC device 1600 of FIG. 6), or any other suitable component. Generally, the package interposer 1704 may spread a connection to a wider pitch or reroute a connection to a different connection. For example, the package interposer 1704 may couple the IC package 1720 (e.g., a die) to a set of BGA conductive contacts of the coupling components 1716 for coupling to the circuit board 1702. In the embodiment illustrated in FIG. 8, the IC package 1720 and the circuit board 1702 are attached to opposing sides of the package interposer 1704; in other embodiments, the IC package 1720 and the circuit board 1702 may be attached to a same side of the package interposer 1704. In some embodiments, three or more components may be interconnected by way of the package interposer 1704.

In some embodiments, the package interposer 1704 may be formed as a PCB, including multiple metal layers separated from one another by layers of dielectric material and interconnected by electrically conductive vias. In some embodiments, the package interposer 1704 may be formed of an epoxy resin, a fiberglass-reinforced epoxy resin, an epoxy resin with inorganic fillers, a ceramic material, or a polymer material such as polyimide. In some embodiments, the package interposer 1704 may be formed of alternate rigid or flexible materials that may include the same materials described above for use in a semiconductor substrate, such as silicon, germanium, and other group Ill-V and group IV materials. The package interposer 1704 may include metal lines 1710 and vias 1708, including but not limited to through-silicon vias (TSVs) 1706. The package interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as RF devices, power amplifiers, power management devices, antennas, arrays, sensors, and microelectromechanical systems (MEMS) devices may also be formed on the package interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 8 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 9 is a block diagram of an example electrical device 1800 that may include one or more IC structures with air gap insulation in place of gate spacers in accordance with any of the embodiments disclosed herein. For example, any suitable ones of the components of the electrical device 1800 may include one or more of the IC device assemblies 1700, IC packages 1650, IC structures 1600, or dies 1502 disclosed herein. A number of components are illustrated in FIG. 9 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 9, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic RAM (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic RAM (eDRAM) or spin transfer torque magnetic RAM (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a handheld or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical device. In some embodiments, the electrical device 1800 may be any other electronic device that processes data.

The following paragraphs provide various examples of the embodiments disclosed herein.

Example 1 provides an IC structure that includes a transistor including a channel region and a region including a doped semiconductor material, where the region is either a source region or a drain region of the transistor; a gate structure coupled to the channel region, where the gate structure includes a gate electrode material and a first electrically conductive material (such a gate structure may be referred to as a “gate contact” of the transistor); a contact structure coupled to the region, where the contact structure includes a second electrically conductive material (such a contact structure may be referred to as a “S/D contact” of the transistor); a gap between the gate structure and the contact structure; and a liner material on at least a portion of a sidewall of the gap, the liner material including aluminum and oxygen.

Example 2 provides the IC structure according to example 1, where the sidewall of the gap with the liner material is a sidewall that is closer to the gate structure than to the contact structure.

Example 3 provides the IC structure according to example 2, where a thickness of the liner material is less than about 1.6 nanometers.

Example 4 provides the IC structure according to any one of examples 2-3, where the liner material is in contact with the first electrically conductive material.

Example 5 provides the IC structure according to any one of examples 2-4, where the liner material is in contact with the gate electrode material.

Example 6 provides the IC structure according to example 1, where the sidewall of the gap with the liner material is a sidewall that is closer to the contact structure than to the gate structure.

Example 7 provides the IC structure according to example 6, where a thickness of the liner material is less than about 1.6 nanometers.

Example 8 provides the IC structure according to any one of examples 6-7, where the liner material is in contact with the second electrically conductive material.

Example 9 provides the IC structure according to any one of examples 1-8, where, in a cross-sectional side view, a portion of the gate structure that is farthest away from the channel region has a rounded profile.

Example 10 provides the IC structure according to any one of examples 1-9, further including a further material at least partially closing the gap between the gate structure and the contact structure (i.e., the gap is between the channel region and the further material).

Example 11 provides the IC structure according to example 10, where the further material includes silicon and nitrogen.

Example 12 provides the IC structure according to any one of examples 10-11, where a thickness of the further material is between about 1 nanometer and 8 nanometers.

Example 13 provides the IC structure according to any one of examples 1-12, where the transistor is a nanoribbon transistor.

Example 14 provides an IC structure that includes a transistor including a channel region and a region including a doped semiconductor material, where the region is either a source region or a drain region of the transistor; a gate structure coupled to the channel region, where the gate structure includes a gate electrode material and a first electrically conductive material; a contact structure coupled to the region, where the contact structure includes a second electrically conductive material; and a gap between the gate structure and the contact structure, where, in a cross-sectional side view, a portion of the gate structure that is farthest away from the channel region is a rounded portion.

Example 15 provides the IC structure according to example 14, where the rounded portion includes tungsten.

Example 16 provides the IC structure according to any one of examples 14-15, further including a further material at least partially closing the gap between the gate structure and the contact structure (i.e., the gap is between the channel region and the further material).

Example 17 provides the IC structure according to example 16, where the further material includes silicon and nitrogen and is in contact with the rounded portion.

Example 18 provides the IC structure according to any one of examples 14-17, further including an interface material between the second electrically conductive material and the region, where the doped semiconductor material includes silicon, and the interface material includes titanium and silicon (e.g., titanium silicide).

Example 19 provides a method of fabricating an IC structure, the method including providing a transistor including a channel region and a region including a doped semiconductor material, where the region is either a source region or a drain region of the transistor; providing a gate structure coupled to the channel region, where the gate structure includes a gate electrode material and a first electrically conductive material; providing a contact structure coupled to the region, where the contact structure includes a second electrically conductive material; providing a gap between the gate structure and the contact structure; and providing a liner material on at least a portion of a sidewall of the gap, the liner material including aluminum and oxygen.

Example 20 provides the method according to example 19, further including providing a further material at least partially closing the gap between the gate structure and the contact structure (i.e., the gap is between the channel region and the further material).

Example 21 provides the method according to any one of examples 19-20, where the IC structure is an IC structure according to any one of the preceding examples.

Example 22 provides an IC package that includes an IC die including an IC structure according to any one of examples 1-18; and a further IC component, coupled to the IC die.

Example 23 provides the IC package according to example 22, where the further IC component includes a package substrate.

Example 24 provides the IC package according to example 22, where the further IC component includes an interposer.

Example 25 provides the IC package according to example 22, where the further IC component includes a further IC die.

Example 26 provides a computing device that includes a carrier substrate and an IC structure coupled to the carrier substrate, where the IC structure is an IC structure according to any one of examples 1-18, or the IC structure is included in the IC package according to any one of examples 22-25.

Example 27 provides the computing device according to example 26, where the computing device is a wearable or handheld computing device.

Example 28 provides the computing device according to examples 26 or 27, where the computing device further includes one or more communication chips.

Example 29 provides the computing device according to any one of examples 26-28, where the computing device further includes an antenna.

Example 30 provides the computing device according to any one of examples 26-29, where the carrier substrate is a motherboard.

Example 31 provides the IC structure according to any one of examples 1-18, where the IC structure includes or is a part of a central processing unit.

Example 32 provides the IC structure according to any one of examples 1-31, where the IC structure includes or is a part of a memory device, e.g., a high-bandwidth memory device.

Example 33 provides the IC structure according to any one of examples 1-32, where the IC structure includes or is a part of a logic circuit.

Example 34 provides the IC structure according to any one of examples 1-33, where the IC structure includes or is a part of input/output circuitry.

Example 35 provides the IC structure according to any one of examples 1-34, where the IC structure includes or is a part of an FPGA transceiver.

Example 36 provides the IC structure according to any one of examples 1-35, where the IC structure includes or is a part of an FPGA logic.

Example 37 provides the IC structure according to any one of examples 1-36, where the IC structure includes or is a part of a power delivery circuitry.

Example 38 provides the IC structure according to any one of examples 1-37, where the IC structure includes or is a part of a Ill-V amplifier.

Example 39 provides the IC structure according to any one of examples 1-38, where the IC structure includes or is a part of PCIE circuitry or DDR transfer circuitry.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) structure, comprising:
a transistor comprising a channel region and a region comprising a doped semiconductor material, wherein the region is either a source region or a drain region of the transistor;
a gate structure coupled to the channel region, wherein the gate structure includes a gate electrode material and a first electrically conductive material;
a contact structure coupled to the region, wherein the contact structure includes a second electrically conductive material;
a gap between the gate structure and the contact structure; and
a liner material on at least a portion of a sidewall of the gap, the liner material comprising aluminum and oxygen.

2. The IC structure according to claim 1, wherein the sidewall of the gap is a sidewall that is closer to the gate structure than to the contact structure.

3. The IC structure according to claim 2, wherein a thickness of the liner material is less than about 1.6 nanometers.

4. The IC structure according to claim 2, wherein the liner material is in contact with the first electrically conductive material.

5. The IC structure according to claim 2, wherein the liner material is in contact with the gate electrode material.

6. The IC structure according to claim 1, wherein the sidewall of the gap is a sidewall that is closer to the contact structure than to the gate structure.

7. The IC structure according to claim 6, wherein a thickness of the liner material is less than about 1.6 nanometers.

8. The IC structure according to claim 6, wherein the liner material is in contact with the second electrically conductive material.

9. The IC structure according to claim 1, wherein, in a cross-sectional side view, a portion of the gate structure that is farthest away from the channel region has a rounded profile.

10. The IC structure according to claim 1, further comprising a further material at least partially closing the gap between the gate structure and the contact structure.

11. The IC structure according to claim 10, wherein the further material includes silicon and nitrogen.

12. The IC structure according to claim 10, wherein a thickness of the further material is between about 1 nanometer and 8 nanometers.

13. The IC structure according to claim 1, wherein the transistor is a nanoribbon transistor.

14. An integrated circuit (IC) structure, comprising:
a transistor comprising a channel region and a region comprising a doped semiconductor material, wherein the region is either a source region or a drain region of the transistor;
a gate structure coupled to the channel region, wherein the gate structure includes a gate electrode material and a first electrically conductive material;
a contact structure coupled to the region, wherein the contact structure includes a second electrically conductive material; and
a gap between the gate structure and the contact structure,
wherein, in a cross-sectional side view, a portion of the gate structure that is farthest away from the channel region is a rounded portion.

15. The IC structure according to claim 14, wherein the rounded portion includes tungsten.

16. The IC structure according to claim 14, further comprising a further material at least partially closing the gap between the gate structure and the contact structure.

17. The IC structure according to claim 16, wherein the further material includes silicon and nitrogen and is in contact with the rounded portion.

18. The IC structure according to claim 14, further comprising an interface material between the second electrically conductive material and the region, wherein the doped semiconductor material includes silicon, and the interface material includes titanium and silicon.

19. A method of fabricating an integrated circuit (IC) structure, the method comprising:
providing a transistor comprising a channel region and a region comprising a doped semiconductor material, wherein the region is either a source region or a drain region of the transistor;
providing a gate structure coupled to the channel region, wherein the gate structure includes a gate electrode material and a first electrically conductive material;
providing a contact structure coupled to the region, wherein the contact structure includes a second electrically conductive material;
providing a gap between the gate structure and the contact structure; and
providing a liner material on at least a portion of a sidewall of the gap, the liner material comprising aluminum and oxygen.

20. The method according to claim 19, further comprising:
providing a further material at least partially closing the gap between the gate structure and the contact structure.
